(19) United States
(12) Patent Application Publication
(10) Pub. No.: US 2026/0143656 A1
(43) Pub. Date: May 21, 2026

(54) ELECTRONIC DEVICE INCLUDING SHIELD STRUCTURE

(71) Applicant: Samsung Electronics Co., Ltd., Suwon-si (KR)

(72) Inventors: Sangmin YE, Suwon-si (KR); Kwanhee HAN, Suwon-si (KR); Taehun KIM, Suwon-si (KR); Woosik CHO, Suwon-si (KR); Seungshik SHIN, Suwon-si (KR); Younju KIM, Suwon-si (KR)

(21) Appl. No.: 19/396,687

(22) Filed: Nov. 21, 2025

Related U.S. Application Data
(63) Continuation of application No. PCT/KR2025/018674, filed on Nov. 13, 2025.

(30) Foreign Application Priority Data
Nov. 15, 2024 (KR) 10-2024-0163138
Jan. 9, 2025 (KR) 10-2025-0003252

(51) Int. Cl. H05K 9/00; H05K 5/00; H05K 5/03

(52) U.S. Cl. CPC H05K 9/0054; H05K 5/0086; H05K 5/03

(57) ABSTRACT

An electronic device includes a speaker, a display on a front surface, a cover on a rear surface, a printed circuit board including radio frequency (RF) circuitry comprising at least one of a power amplifier or a power management IC spaced apart from the speaker, a battery spaced apart from the printed circuit board, a first shield sheet corresponding to at least a portion of the battery and the printed circuit board and disposed between the display and the printed circuit board, the first shield sheet configured to shield a magnetic field generated by the RF circuitry, and a second shield sheet corresponding to at least a portion of the battery and the printed circuit board and disposed between the cover and the battery and the printed circuit board, the second shield sheet including an opening in an area adjacent to the RF circuitry and configured to radiate a magnetic field generated by the RF circuitry through the opening.

### CROSS-REFERENCE TO RELATED APPLICATIONS

This application is a continuation of International Application No. PCT/KR 2025/018674 designating the United States, filed on Nov. 13, 2025, in the Korean Intellectual Property Receiving Office and claiming priority to Korean Patent Application Nos. 10-2024-0163138, filed on Nov. 15, 2024, and 10-2025-0003252, filed on Jan. 9, 2025, in the Korean Intellectual Property Office, the disclosures of each of which are incorporated by reference herein in their entireties.

### BACKGROUND

### Field

The disclosure relates to an electronic device including a shield structure.

### Description of Related Art

Wireless electronic devices such as mobile phones must comply with the hearing aid compatibility (HAC) regulations of the Federal Communications Commission (FCC) so as to avoid interfering with hearing aid users. The magnetic field (H-field) standard of the HAC regulations of the FCC evaluates whether a hearing aid can smoothly operate by receiving magnetic signals from the electronic device.

The above-described information may be provided as related art for the purpose of assisting in understanding the disclosure. No assertion or determination is made as to whether any of the above might be applicable as prior art with regard to the disclosure.

### SUMMARY

An electronic device according to an example embodiment of the disclosure may include a speaker.

According to an example embodiment of the disclosure, the electronic device may include a display disposed on a front surface of the electronic device.

According to an example embodiment of the disclosure, the electronic device may include a cover disposed on a rear surface of the electronic device.

According to an example embodiment of the disclosure, the electronic device may include a printed circuit board including radio frequency (RF) circuitry including at least one of a power amplifier and/or a power management IC spaced apart from the speaker.

According to an example embodiment of the disclosure, the electronic device may include a battery spaced apart from the printed circuit board.

According to an example embodiment of the disclosure, the electronic device may include a first shield sheet corresponding to at least a portion of the battery and the printed circuit board and disposed between the display and the printed circuit board. The first shield sheet may be configured to shield a magnetic field generated by the RF circuitry from being directed toward the front surface.

According to an example embodiment of the disclosure, the electronic device may include a second shield sheet corresponding to at least a portion of the battery and the printed circuit board and disposed between the cover and the battery and the printed circuit board. The second shield sheet may include an opening in an area adjacent to the RF circuitry that may be configured to radiate a magnetic field generated by the RF circuitry through the opening.

In an example embodiment of the disclosure, the electronic device may include at least one coil disposed on the second shield sheet.

In an example embodiment of the disclosure, the second shield sheet may be separated into two sheets by a slit or a slit-shaped opening.

In an example embodiment of the disclosure, the display may include a copper sheet on the rear surface thereof.

In an example embodiment of the disclosure, the opening may be positioned between an area corresponding to the RF circuitry and an area corresponding to the battery.

In an example embodiment of the disclosure, the slit may be formed in a cross direction of the electronic device.

In an example embodiment of the disclosure, the slit may be located between an area corresponding to the RF circuitry and an area corresponding to the battery.

In an example embodiment of the disclosure, the second shield sheet may include an opening in an area corresponding to at least a portion of the RF circuitry.

In an example embodiment of the disclosure, at least one of the first shield sheet and the second shield sheet may be spaced apart from the speaker by a specified distance.

In an example embodiment of the disclosure, the first shield sheet and the second shield sheet may include at least one of a high-permeability magnetic material having a permeability greater than a threshold permeability and a conductive metal.

In an example embodiment of the disclosure, the opening may correspond to an area in which a high-permeability magnetic material and/or a conductive metal is not present.

In an example embodiment of the disclosure, the second shield sheet may have a step between the opening and an area other than the opening.

In an example embodiment of the disclosure, the slit may correspond to an area in which a high-permeability magnetic material and/or a conductive metal is not present.

In an example embodiment of the disclosure, the second shield sheet may have a step between the slit and an area other than the slit.

In an example embodiment of the disclosure, the electronic device may include at least one processor comprising processing circuitry.

In an example embodiment of the disclosure, the electronic device may include memory configured to store instructions.

In an example embodiment of the disclosure, t at least one processor, individually and/or collectively may be configured to execute the instructions and to cause the electronic device to request a base station to restrict application of uplink multiple input multiple output (MIMO) based on a hearing aid being communicatively connected and used for a call.

In an example embodiment of the disclosure, a magnetic field shield sheet may include a first cover layer.

In an example embodiment of the disclosure, a magnetic field shield sheet may include a second cover layer.

In an example embodiment of the disclosure, a magnetic field shield sheet may include a shield layer disposed between the first cover layer and the second cover layer and including a high-permeability magnetic material having a permeability greater than a threshold permeability.

In an example embodiment of the disclosure, the shield layer of the magnetic field shield sheet may include a slit area and/or an opening area in which the high-permeability magnetic material is not present.

In an example embodiment of the disclosure, the magnetic field shield sheet may have a step between the slit area and/or the opening area and an area other than the slit area or the opening area.

In an example embodiment of the disclosure, the slit area of the magnetic field shield sheet may include a magnetic field shield sheet having a specified interval.

In an example embodiment of the disclosure, the slit area and/or the opening area of the magnetic field shield sheet may allow a magnetic field to be radiated.

In an example embodiment of the disclosure, the slit area of the magnetic field shield sheet may be disposed in a specified direction.

### BRIEF DESCRIPTION OF THE DRAWINGS

With regard to the description of the drawings, the same or like reference signs may be used to designate the same or like elements. Further, the above and other aspects, features and advantages of certain embodiments of the present disclosure will be more apparent from the following detailed description, taken in conjunction with the accompanying drawings, in which:

FIG. 1 is a block diagram illustrating an example configuration of an example electronic device according to various embodiments;

FIG. 2A is a diagram illustrating a front view of an electronic device according to various embodiments;

FIG. 2B is a diagram illustrating a rear view of the electronic device according to various embodiments;

FIG. 2C is a diagram illustrating a side view of the electronic device according to various embodiments;

FIG. 3 is a diagram illustrating an electronic device with a cover of the electronic device removed, as viewed from the rear according to various embodiments;

FIG. 4 is a diagram illustrating the electronic device with a cover of the electronic device removed, as viewed from the rear according to various embodiments;

FIG. 5 is a diagram illustrating an electronic device with a display of the electronic device removed, as viewed from the front according to various embodiments;

FIG. 6 is a cross-sectional view of the electronic device of FIG. 2B, taken along C1-C2 according to various embodiments;

FIG. 7A is a diagram illustrating values of the H-field measured in area A of FIG. 2A for the electronic device when a front surface shield sheet and a rear surface shield sheet are not present according to various embodiments;

FIG. 7B is a diagram classifying the H-field measured in FIG. 7A according to a magnetic field strength standard of the HAC regulations of the FCC according to various embodiments;

FIG. 7C is a diagram illustrating values of the H-field measured in area A of FIG. 2A of the electronic device when only a front surface shield sheet is present according to various embodiments;

FIG. 7D is a diagram classifying the H-field measured in FIG. 7C according to a magnetic field strength standard of the HAC regulations of the FCC according to various embodiments;

FIG. 7E is a diagram illustrating values of the H-field measured in area A of FIG. 2A of the electronic device 100 which includes a front surface shield sheet and a rear surface shield sheet including a slit according to various embodiments;

FIG. 7F is a diagram classifying the H-field measured in FIG. 7E according to a magnetic field strength standard of the HAC regulations of the FCC according to various embodiments;

FIG. 7G is a diagram illustrating values of the H-field measured in area A of FIG. 2A of the electronic device which includes a front surface shield sheet and a rear surface shield sheet including an opening according to various embodiments; and

FIG. 7H is a diagram classifying the H-field measured in FIG. 7G according to a magnetic field strength standard of the HAC regulations of the FCC according to various embodiments.

### DETAILED DESCRIPTION

Recently, to increase data traffic and expand coverage, communication protocols (e.g., uplink multiple input multiple output (UL MIMO), 2TX (transmitter)) have been applied, resulting in increased current consumption in radio frequency (RF) circuitry, which makes it difficult to satisfy the H-field standard of the HAC.

As more electronic devices adopt near field communication (NFC) or wireless charging circuitry, a shield layer having high permeability characteristics for blocking magnetic fields generated in the NFC or wireless charging circuitry is disposed near the RF circuitry of the electronic device.

The high-permeability shield layer disposed near the RF circuitry is easily magnetized, leading to a difficulty in that magnet fields are concentrated near a speaker (e.g., a receiver) instead of being emitted to the outside through a cover of the electronic device.

To address the problem that magnetic fields emitted from RF circuitry cannot be emitted to the outside by shielding the entire area where the RF circuitry or wires overlap coils, an opening or a slit may be formed in an electronic device including a shield structure according to an embodiment of the disclosure by removing a portion of the shield layer corresponding to the area where the RF circuitry or wires and coils overlap.

An electronic device including a shielding structure according to an embodiment of the disclosure may allow magnetic fields emitted from the RF circuitry to be directed to the outside of the electronic device by removing a portion of the shield layer corresponding to the area where the RF circuitry or wires overlap coils or by forming a slit.

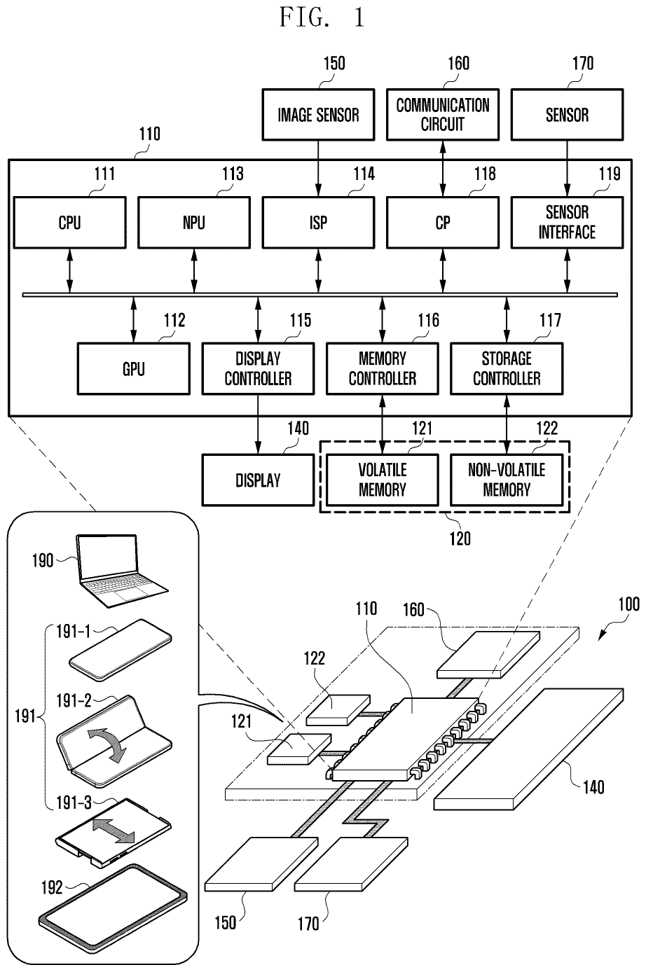

FIG. 1 is a block diagram illustrating an example configuration of an example electronic device 100 according to various embodiments.

Referring to FIG. 1, the electronic device 100 may be one of various types of electronic devices, such as a notebook computer 190, smartphones 191 having various form factors (e.g., a bar-type smartphone 191-1, a foldable smartphone 191-2, or a slidable (or rollable) smartphone 191-3), a tablet PC 192, a cellular telephone (not shown), and any other similar computing devices (not shown). The components illustrated in FIG. 1, the relationships thereof, and the functions thereof are merely for illustration, and are not intended to limit the implementations described or claimed in the disclosure thereto. The electronic device 100 may be referred to as a mobile device, a user equipment, a multifunctional device, a portable device, or a server.

The electronic device 100 may comprise various components including at least one processor (e.g., including processing circuitry) 110 (hereinafter, the processor 110), at least one memory 120 (hereinafter, the memory 120), at least one display 140 (hereinafter, the display 140), at least one image sensor 150 (hereinafter, the image sensor 150), at least one communication circuitry 160 (hereinafter, the communication circuitry 160), and/or at least one sensor 170 (hereinafter, the sensor 170). The aforementioned components are merely an example. For example, the electronic device 100 may comprise other components (e.g., a power management integrated circuitry (PMIC), an audio processing circuitry, an antenna, a rechargeable battery, or an input/output interface). For example, some components may be omitted from the electronic device (100). For example, some components may be integrated into one component.

The processor 110 may include various processing circuitry and may be implemented as one or more integrated circuit (or circuitry) (IC) chips and may perform various data processing. The processor 110 may include at least one electrical circuitry and may process instructions (or program, data, and so on) stored in the memory 120 individually or collectively in a distributed manner. The processor 110 may include a processor assembly that includes one or more processing circuitries. The processor may include any processing circuitry that may be operative for controlling operations and performance of one or more components (e.g., the memory 120, a display 140, the image sensor 150, the communication circuitry 160, and/or the sensor 170) of the electronic device. For example, the processor 110 (e.g., an application processor (AP)) may be implemented as a system on chip (SoC) (e.g., one chip or chipset). For example, the processor 110 may be implemented as a plurality of cores (or at least one core circuitry), a plurality of chips, or a plurality of chipsets. For example, the processor 110 may comprise one or more processing circuitry. For example, the processor 110 may comprise one or more processing circuitry which are individually and/or collectively configured to perform various functions of the present disclosure. As a non-limiting example, at least a portion of the processor 110 may be included in a first chip of the electronic device 100 and at least another portion of the processor 110 may be included in a second chip of the electronic device 100 different from the first chip of the electronic device 100.

For example, the processor 110 may comprise a central processing unit (CPU) 111, a graphics processing unit (GPU) 112, a neural processing unit (NPU) 113, an image signal processor (ISP) 114, a display controller 115, a memory controller 116, a storage controller 117, a communication processor (CP) 118, and/or a sensor interface 119. These components of the processor 110 are merely of an example. For example, the processor 110 may further comprise other components. For example, some components of the processor 110 may be omitted from the processor 110. For example, some components of the processor 110 may be included as separate components of the electronic device 100 outside the processor 110. For example, various components of the processor 110 (e.g., the memory controller 116) may be included in other components of the electronic device 100 (e.g., at least a portion of the memory 120, an interface (e.g., usable for connecting to at least one component of the electronic device 100), the display 140, and/or the image sensor 150).

The processor 110 may cause other components of the electronic device 100 to perform various operations by executing instructions stored in the memory 120. The CPU 111 (or a central processing circuitry) may be configured to control the components of the processor 110 based on execution of instructions stored in the memory 120 (e.g., the volatile memory 121 and/or the non-volatile memory 122). The GPU 112 (or a graphic processing circuitry) may be configured to execute parallel computations (e.g., rendering). The NPU 113 (or a neural processing circuitry, or an artificial intelligence (AI) chip) may be configured to execute operations (e.g., convolution computations) for an artificial intelligence model. The ISP 114 (or an image signal processing circuitry) may be configured to process a raw image obtained from the image sensor 150 in a format suitable for a component in the electronic device 100 or a component of the processor 110. The display controller 115 (or a display control circuitry, or a display processing unit (DPU)) may be configured to process an image obtained from the CPU 111, the GPU 112, the ISP 114, or the memory 120 (e.g., the volatile memory 121) in a format suitable for the display 140. The memory controller 116 (or a memory control circuitry) may be configured to control reading data from the volatile memory 121 and writing data to the volatile memory 121. The storage controller 117 (or a storage control circuitry) may be configured to control reading data from the non-volatile memory 122 and writing data to the non-volatile memory 122. The CP 118 (or a communication processing circuitry) may be configured to process data obtained from a component of the processor 110 in a format suitable for transmission to another electronic device via the communication circuitry 160, or to process data obtained from another electronic device via the communication circuitry 160 in a format suitable for processing of the component of the processor 110. For example, the communication circuitry 160 may comprise one or more communication circuitry. The sensor interface 119 (or a sensing data processing circuitry, a sensor hub) may be configured to process data on a state of the electronic device 100 and/or a state around the electronic device 100, obtained through the sensor 170, in a format suitable for a component of the processor 110.

The memory 120 may comprise one or more storage mediums (or one or more storage devices). For example, the memory 120 may include a memory assembly that includes one or more storage mediums. For example, the one or more storage mediums may comprise a permanent memory (e.g., the non-volatile memory 122) such as a hard drive, a flash memory, a read-only memory (ROM), a semi-permanent memory (e.g., the volatile memory 121) such as a random access memory (RAM), a storage (or a storage assembly) of any other suitable type, or any combination thereof. The memory 120 may comprise a cache memory which is a memory of one or more different types used to store data for performing a function or feature of the electronic device 100 at least temporarily. As a non-limiting example, the cache memory may be included in the processor 110. The memory 120 may be fixedly embedded within the electronic device 100, or may be incorporated onto one or more suitable types of components that may be repeatedly inserted into the electronic device 100, and removed from the electronic device 100 (e.g., a subscriber identity module (SIM) card, and/or a secure digital (SD) card).

For example, the memory 120 may store one or more software applications such as an operating system (or a system) software application, a firmware software application, a driver software application, a plug-in (e.g., add-in, add-on, and/or applet) software application, and/or any other suitable software application. For example, the one or more software applications may include instructions executable by the processor 110. For example, the memory 120 may store instructions callable by an application programming interface (API). For example, the memory 120 may store instructions in a library.

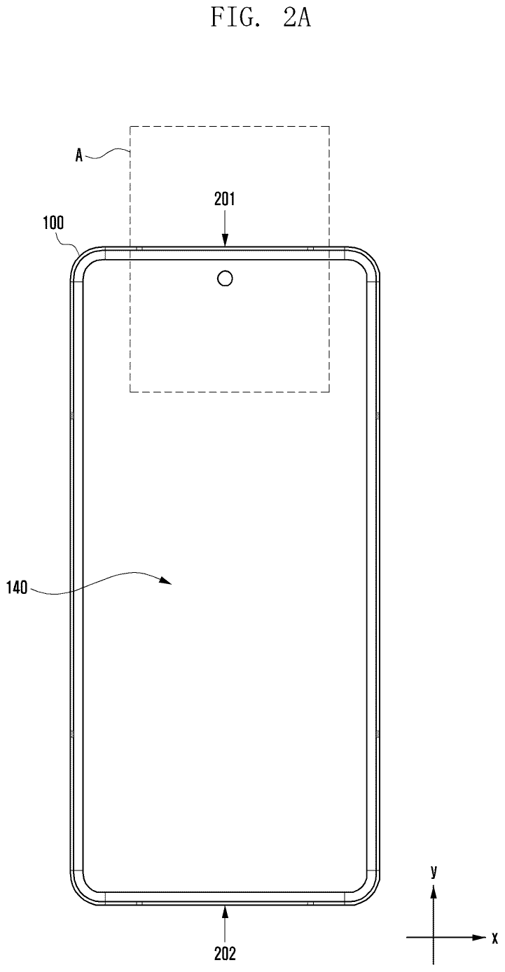

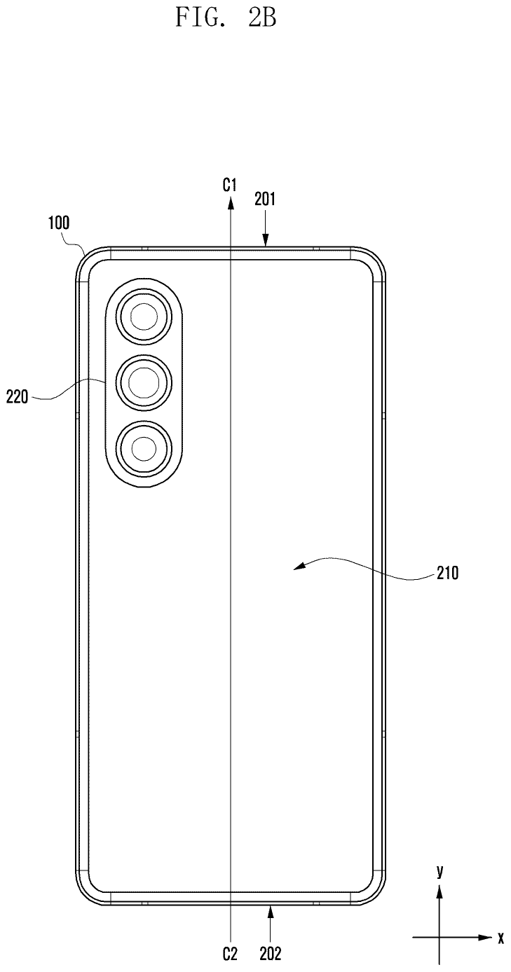

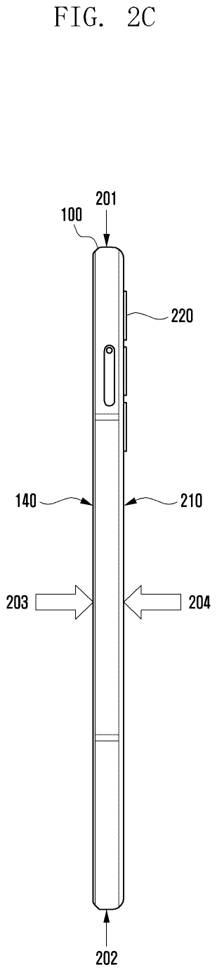

FIG. 2A is a diagram illustrating a front view of an electronic device 100 according to various embodiments.

FIG. 2B is a diagram illustrating a rear view of the electronic device 100 according to various embodiments.

FIG. 2C is a diagram illustrating a side view of the electronic device 100 according to various embodiments.

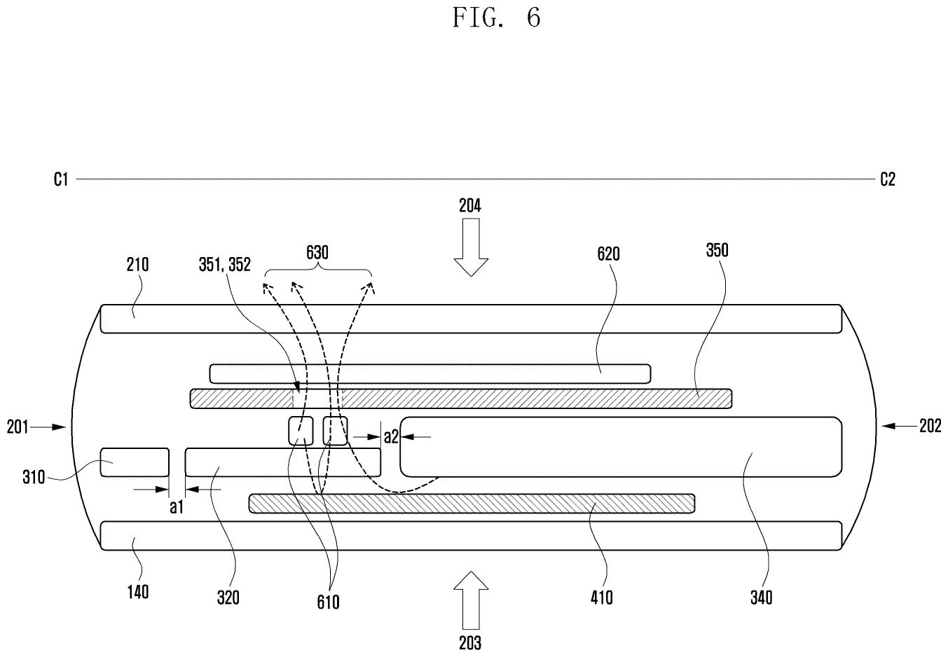

Referring to FIGS. 2A, 2B, and 2C, a display 140 may be disposed on a front surface 203 of the electronic device 100. A cover 210 may be disposed on a rear surface 204 of the electronic device 100. A camera 220 may be disposed on at least a portion of the rear surface 204 of the electronic device 100. The electronic device 100 may include a first edge area 201 and a second edge area 202. A speaker (e.g., the speaker 310 of FIG. 6) may be disposed in an area adjacent to the first edge area 201.

In FIG. 2A, area A may include an area for measuring a magnetic field (H-field) of the electronic device 100 in accordance with the HAC regulations of the FCC.

The electronic device 100 of FIG. 2A may include at least one processor 110, at least one communication circuit 160, and memory 120 configured to store instructions. The instructions, when executed individually or collectively by the at least one processor 110, may cause the electronic device 100 to request a base station or a network to restrict the application of UL MIMO based on the fact that a hearing aid is communication-connected and used for a call. The hearing aid may include a device external to the electronic device 100. However, the disclosure is not limited thereto, and the hearing aid may include a device integrated with the electronic device 100.

In an embodiment, when an external electronic device (e.g., a hearing aid) is connected to a terminal and is used for a call, the instructions, when executed individually or collectively by the at least one processor 110, may cause the electronic device 100 to request a base station or a network to restrict the application of UL MIMO. For example, the electronic device 100 may request a base station to change or lower its maximum UL MIMO layer, which is related to the UL MIMO capability of the electronic device 100, to 1 through UE assistance information.

For example, when the electronic device 100 capable of performing 4×4 UL MIMO conducts a call using an external electronic device (e.g., a hearing aid), the electronic device 100 may request the base station, through UE assistance information, to change to 2×2 UL MIMO (e.g., two layers) that can satisfy the magnetic field strength standard according to HAC regulations.

FIGS. 2A, 2B, and 2C illustrate the electronic device 100 as a bar-type smartphone 191-1 of FIG. 1, but the disclosure is not limited thereto.

In an embodiment, the electronic device 100 may be one of various types of electronic devices, such as a laptop 190, smartphones 191 having various form factors (e.g., a bar-type smartphone 191-1, a foldable-type smartphone 191-2, or a slidable (or rollable)-type smartphone 191-3), a tablet 192, a cellular phone (not illustrated), and other similar computing devices (not illustrated).

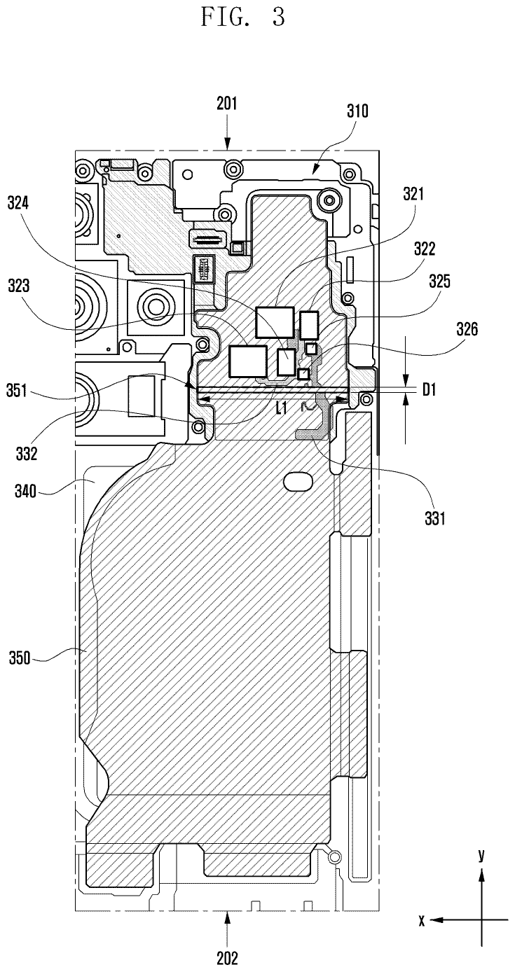

FIG. 3 is a diagram illustrating the electronic device 100 with a cover 210 of the electronic device 100 removed, as viewed from the rear according to various embodiments.

In an embodiment, the electronic device 100 may include a speaker 310, a printed circuit board 320, a battery 340, and a rear surface shield sheet 350.

In an embodiment, the speaker 310 may be disposed to be spaced apart from the printed circuit board 320 by a first specified distance. The printed circuit board 320 may be disposed at a second specified distance from the battery 340.

In an embodiment, the first specified distance and the second specified distance may be different from each other. However, the disclosure is not limited thereto, and the first specified distance and the second specified distance may be the same.

In an embodiment, the speaker 310 may include a receiver. The speaker 310 may be disposed, for example, adjacent to the first edge area 201 of the electronic device 100.

In an embodiment, the printed circuit board 320 may include radio frequency (RF) circuitry. The RF circuitry may include one or more RF components 321, 322, 323, 324, 325, and 326. The RF circuitry may include one or more wires 331 and 332 electrically connecting between the RF components 321, 322, 323, 324, 325, and 326.

In an embodiment, the RF circuitry may include at least one of a power amplifier or a power management IC (PMIC). In an embodiment, one or more wires 331 and 332 may be disposed on the printed circuit board 320 and may include a conductive metal (e.g., copper). A first wire 331 may be disposed on the printed circuit board 320 in the first edge area 201 in a direction from the first edge area 201 toward the second edge area 202 (or in the y-axis direction).

For example, the first direction (e.g., the y-axis direction) may include a direction crossing from the first edge area 201 to the second edge area 202. The second direction (e.g., the x-axis direction) may include a direction substantially perpendicular to the first direction (e.g., the y-axis direction).

In an embodiment, a second wire 332 may be disposed on the printed circuit board 320 in the second direction (e.g., the x-axis direction).

In an embodiment, the rear surface shield sheet 350 may cover at least a portion of the printed circuit board 320 and the battery 340.

In an embodiment, at least a portion of the rear surface shield sheet 350 may include a slit 351. The rear surface shield sheet 350 may include a magnetic field shield layer including a high-permeability magnetic material or a conductive metal between cover layers protecting the outer shape of the shield sheet. The slit 351 may be an area in which at least a portion of the magnetic field shield layer of the rear surface shield sheet 350 is removed. However, the disclosure is not limited thereto, and the slit 351 may include an opening in which all the cover layers and the magnetic field shield layer are removed so that an opposite area is visible.

In an embodiment, the slit 351 of the rear surface shield sheet 350 may be disposed in an area adjacent to RF components 321, 322, 323, 324, 325, and 326 and wires 331 and 332 on the printed circuit board 320.

In an embodiment, the slit 351 of the rear surface shield sheet 350 may be disposed in an area corresponding to the RF components 321, 322, 323, 324, 325, and 326 and the wires 331 and 332 on the printed circuit board 320.

In an embodiment, the slit 351 of the rear surface shield sheet 350 may be disposed between the printed circuit board 320 and the battery 340.

In an embodiment, the slit 351 of the rear surface shield sheet 350 may have a specified interval D1.

In an embodiment, the slit 351 of the rear surface shield sheet 350 may have a specified depth L1.

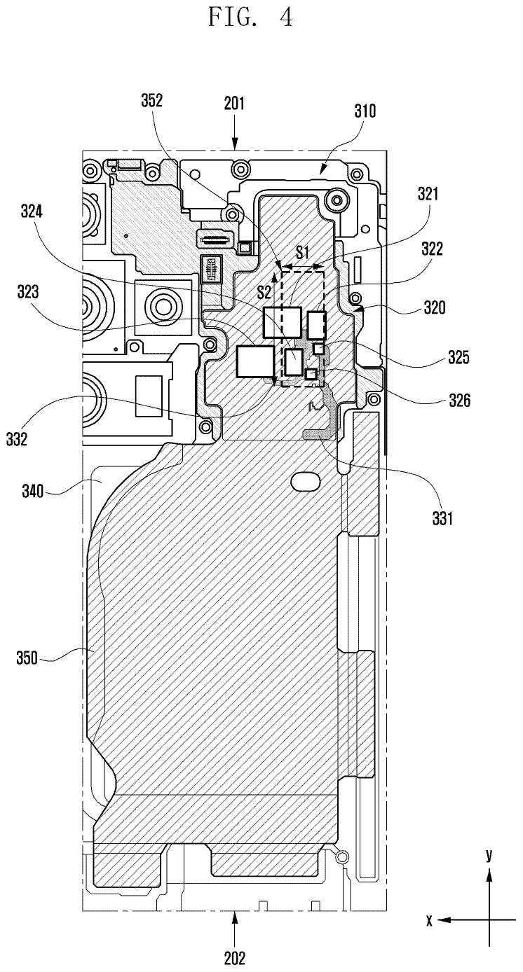

FIG. 4 is a diagram illustrating the electronic device 100 with a cover 210 of the electronic device 100 removed, as viewed from the rear according to various embodiments.

In an embodiment, the electronic device 100 may include a speaker 310, a printed circuit board 320, a battery 340, and a rear surface shield sheet 350.

The electronic device 100 of FIG. 4 has the same components as the electronic device 100 of FIG. 3, and differs in a structure or shape of the rear surface shield sheet 350. In describing the electronic device 100 of FIG. 4, portions overlapping with the description of the electronic device 100 of FIG. 3 may not be mentioned.

In an embodiment, the rear surface shield sheet 350 of FIG. 4 may include an opening 352.

In an embodiment, the rear surface shield sheet 350 may cover at least a portion of the printed circuit board 320 and the battery 340.

In an embodiment, at least a portion of the rear surface shield sheet 350 may include the opening 352. The rear surface shield sheet 350 may include a magnetic field shield layer that includes a high-permeability magnetic material or a conductive metal between cover layers protecting the outer shape of the shield sheet. The opening 352 may be an area in which at least a portion of the magnetic field shield layer of the rear surface shield sheet 350 is removed. However, the disclosure is not limited thereto, and the opening 352 may include an aperture in which all the cover layers and the magnetic field shield layer are removed so that an opposite area is visible.

In an embodiment, the opening 352 of the rear surface shield sheet 350 may be disposed in an area adjacent to RF components 321, 322, 323, 324, 325, and 326 and wires 331 and 332 on the printed circuit board 320.

In an embodiment, the opening 352 of the rear shield sheet 350 may be disposed in an area corresponding to the RF components 321, 322, 323, 324, 325, and 326 and the wires 331 and 332 on the printed circuit board 320.

In an embodiment, the opening 352 of the rear surface shield sheet 350 may have a specified area. The opening 352 of the rear surface shield sheet 350 may correspond to an area including a substantially square or rectangular shape. For example, the opening 352 of the rear surface shield sheet 350 may include a square shape having a first length S1 in a horizontal direction and a second length S2 in a vertical direction.

In an embodiment, the rear surface shield sheet 350 may be separated into two areas or sheets by the slit 351 (see, e.g., FIG. 3) or the opening 352.

In an embodiment, the first length S1 and the second length S2 may have different lengths. However, the disclosure is not limited thereto, and the first length S1 and the second length S2 may be the same.

In an embodiment, although the opening 352 of the rear surface shield sheet 350 has been described as a square or rectangular shape, the disclosure is not limited thereto, and the opening 352 of the rear surface shield sheet 350 may include various shapes. For example, the opening 352 of the rear surface shield sheet 350 may include a circular shape, a polygonal shape (e.g., a triangular shape or a pentagonal shape), or a combined shape thereof. For example, the opening 352 of the rear surface shield sheet 350 may include not only a geometric shape but also an irregular shape.

In an embodiment, the speaker 310 may be disposed to be spaced apart from the printed circuit board 320 by a first specified distance. The printed circuit board 320 may be disposed at a second specified distance from the battery 340.

In an embodiment, the first specified distance and the second specified distance may be different from each other. However, the disclosure is not limited thereto, and the first specified distance and the second specified distance may be the same.

In an embodiment, the speaker 310 may include a receiver. The speaker 310 may be disposed, for example, adjacent to the first edge area 201 of the electronic device 100.

In an embodiment, the printed circuit board 320 may include radio frequency (RF) circuitry. The RF circuitry may include one or more RF components 321, 322, 323, 324, 325, and 326. The RF circuitry may include one or more wires 331 and 332 electrically connecting between the RF components 321, 322, 323, 324, 325, and 326.

In an embodiment, one or more wires 331 and 332 may be disposed on the printed circuit board 320 and may include a conductive metal (e.g., copper). A first wire 331 may be disposed on the printed circuit board 320 in the first edge area 201 in a direction from the first edge area 201 toward the second edge area 202 (or in the y-axis direction).

For example, the first direction (e.g., the y-axis direction) may include a direction crossing from the first edge area 201 to the second edge area 202. The second direction (e.g., the x-axis direction) may include a direction substantially perpendicular to the first direction (e.g., the y-axis direction).

In an embodiment, a second wire 332 may be disposed on the printed circuit board 320 in the second direction (e.g., the x-axis direction).

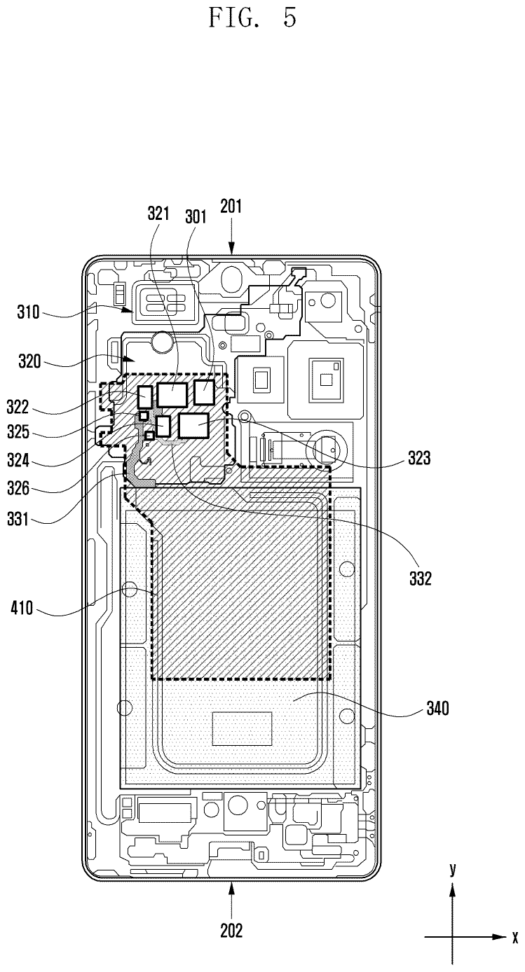

FIG. 5 is a diagram illustrating the electronic device 100 with a display 140 of the electronic device 100 removed, as viewed from the front according to various embodiments.

In an embodiment, the electronic device 100 may include a speaker 310, a printed circuit board 320, a battery 340, and a front surface shield sheet 410.

In describing the electronic device 100 of FIG. 5, portions overlapping with the description of the electronic device 100 of FIGS. 3 and 4 may not be repeated.

In an embodiment, the speaker 310 may be disposed to be spaced apart from the printed circuit board 320 by a first specified distance. The printed circuit board 320 may be disposed at a second specified distance from the battery 340.

In an embodiment, the first specified distance and the second specified distance may be different from each other. However, the disclosure is not limited thereto, and the first specified distance and the second specified distance may be the same.

In an embodiment, the speaker 310 may include a receiver. The speaker 310 may be disposed, for example, adjacent to the first edge area 201 of the electronic device 100.

In an embodiment, the printed circuit board 320 may include radio frequency (RF) circuitry. The RF circuitry may include one or more RF components 321, 322, 323, 324, 325, and 326. The RF circuitry may include at least one wire electrically connecting between the RF components 321, 322, 323, 324, 325, and 326.

In an embodiment, one or more wires 331 and 332 may be disposed on the printed circuit board 320 and may include a conductive metal (e.g., copper). A first wire 331 may be disposed on the printed circuit board 320 in the first edge area 201 in a direction from the first edge area 201 toward the second edge area 202 (or in the y-axis direction).

For example, the first direction (e.g., the y-axis direction) may include a direction crossing from the first edge area 201 to the second edge area 202. The second direction (e.g., the x-axis direction) may include a direction substantially perpendicular to the first direction (e.g., the y-axis direction).

In an embodiment, a second wire 332 may be disposed on the printed circuit board 320 in the second direction (e.g., the x-axis direction).

In an embodiment, the front surface shield sheet 410 may cover at least a portion of the printed circuit board 320 and the battery 340.

In an embodiment, the front surface shield sheet 410 may include a magnetic field shield layer that includes a high-permeability magnetic material or a conductive metal between cover layers protecting the outer shape of the shield sheet.

FIG. 6 is a cross-sectional view of the electronic device 100 of FIG. 2B, taken along line C1-C2 according to various embodiments.

In an embodiment, the electronic device 100 may include a display 140, a cover 210, a speaker 310, a printed circuit board 320, a battery 340, a rear surface shield sheet 350, a front surface shield sheet 410, and coil circuitry 620.

In an embodiment, the display 140 may be disposed on the front surface 203 of the electronic device 100. The display 140 may include a copper sheet on the rear surface thereof.

In an embodiment, the cover 210 may be disposed on the rear surface 204 of the electronic device 100.

In an embodiment, the coil circuitry 620 may include circuitry for near field communication (NFC) and/or circuitry for wireless charging.

In an embodiment, the speaker 310 may be disposed to be spaced apart from the printed circuit board 320 by a first specified distance a1. The printed circuit board 320 may be disposed at a second specified distance a2 from the battery 340.

In an embodiment, the first specified distance a1 and the second specified distance a2 may be different from each other. However, the disclosure is not limited thereto, and the first specified distance a1 and the second specified distance a2 may be the same.

In an embodiment, the speaker 310 may be disposed adjacent to the first edge area 201 of the electronic device 100. At least a portion of the speaker 310 may correspond to the first edge area 201 of the electronic device 100. The battery 340 may be disposed such that at least a portion thereof is adjacent to the second edge area 202 of the electronic device 100.

In an embodiment, a printed circuit board (e.g., a sub-PCB) and/or a speaker may be disposed between at least a portion of the battery 340 and the second edge area 202 of the electronic device 100.

In an embodiment, the printed circuit board 320 may include at least one RF circuity 610. The RF circuitry 610 may include one or more RF components 321, 322, 323, 324, 325, and 326 and one or more wires 331 and 332 of FIGS. 3, 4, and 5.

In an embodiment, the rear surface shield sheet 350 may cover at least a portion of the printed circuit board 320 and the battery 340.

In an embodiment, the rear surface shield sheet 350 may include a slit 351 or an opening 352 in an area corresponding to or adjacent to the RF circuitry 610.

In an embodiment, the front surface shield sheet 410 may cover at least a portion of the printed circuit board 320 and the battery 340.

In an embodiment, the rear surface shield sheet 350 may include a magnetic field shield layer that includes a high-permeability (e.g., having a higher permeability that a reference or threshold level) magnetic material or a conductive metal between cover layers protecting the outer shape of the shield sheet. The slit 351 or the opening 352 may be an area in which at least a portion of the magnetic field shield layer of the rear surface shield sheet 350 is removed. However, the disclosure is not limited thereto, and the opening 352 may include an aperture in which all the cover layers and the magnetic field shield layer are removed so that an opposite area is visible.

In an embodiment, the front surface shield sheet 410 may be disposed between the printed circuit board 320 and the display 140.

In an embodiment, the rear surface shield sheet 350 may be disposed between the cover 210 and a plane of the battery 340/printed circuit board 320. The rear surface shield sheet 350 may be disposed between the cover 210 and the battery 340 and the printed circuit board 320.

In an embodiment, the front surface shield sheet 410 may include a magnetic field shield layer including a high-permeability magnetic material or a conductive metal between cover layers that protect the outer shape of the shield sheet.

In an embodiment, the front surface shield sheet 410 may be disposed to face the front surface 203 of the electronic device 100. The rear surface shield sheet 350 may be disposed to face the rear surface 204 of the electronic device 100.

In an embodiment, when the speaker 310, the printed circuit board 320, and the battery 340 are disposed to include or to be adjacent to substantially the same plane (e.g., a first plane), the front surface shield sheet 410 may be disposed between the first plane and the display 140.

In an embodiment, when the speaker 310, the printed circuit board 320, and the battery 340 are disposed to include or to be adjacent to substantially the same plane (e.g., a first plane), the rear surface shield sheet 350 may be disposed between the first plane and the coil circuitry 620.

In an embodiment, when the speaker 310, the printed circuit board 320, and the battery 340 are disposed to include or to be adjacent to substantially the same plane (e.g., a first plane), the rear surface shield sheet 350 may be disposed between the first plane and the cover 210.

In an embodiment, magnetic signals 630 from the battery 340 and/or the RF circuitry 610 may be absorbed by the front surface shield sheet 410 and the rear surface shield sheet 350, or may be emitted toward the rear surface 204 of the electronic device 100 through the slit 351 or the opening 352 of the rear surface shield sheet 350. The front surface shield sheet 410 may direct magnetic signals 630 emitted from the battery 340 and/or the RF circuitry 610 toward the rear surface 204.

In an embodiment, the rear surface shield sheet 350 may include not only the slit 351 and/or the opening 352 but also a magnetic field shield layer removal area based on various shapes.

In an embodiment, the rear surface shield sheet 350 may include a magnetic field shield layer removal area in various areas of the rear surface shield sheet 350.

In an embodiment, the electronic device 100 may include only the front surface shield sheet 410 without the rear surface shield sheet 350.

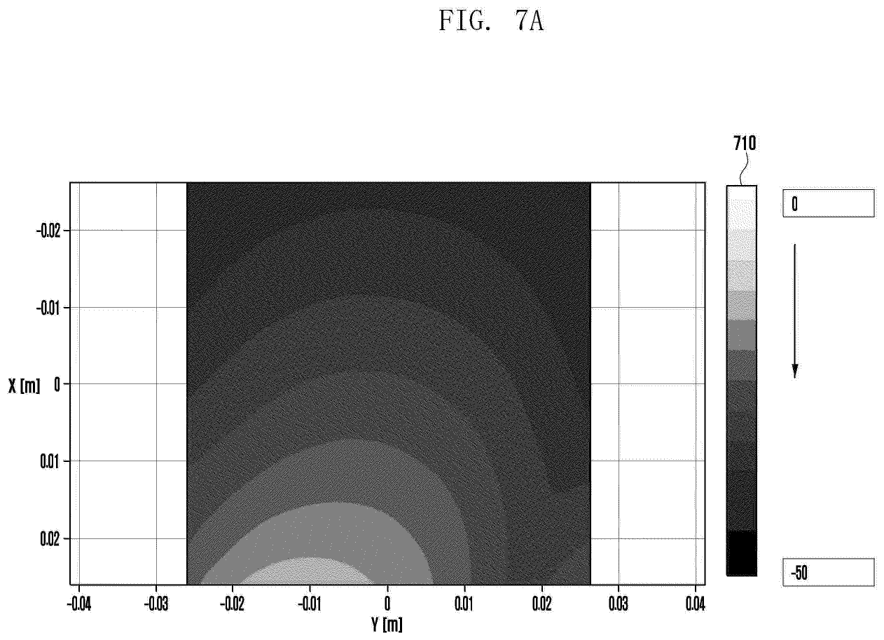

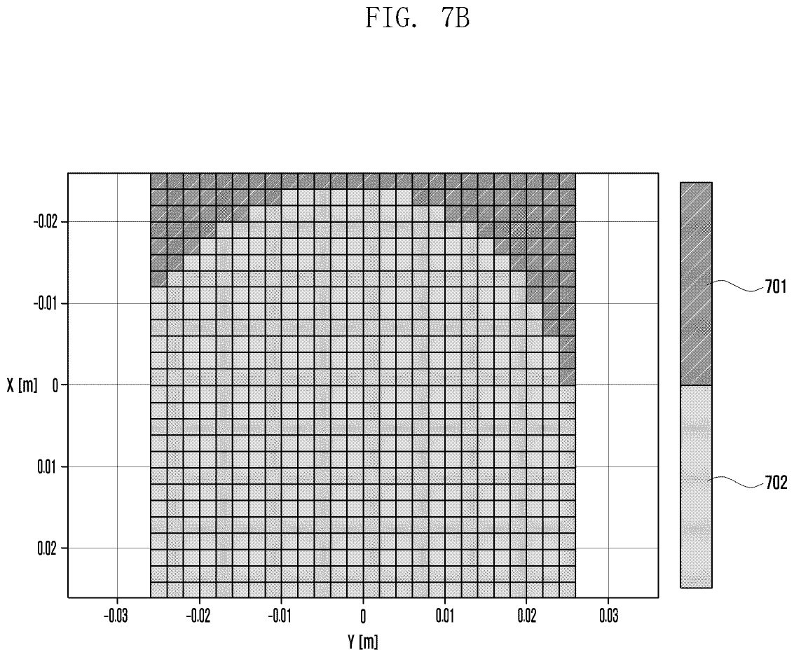

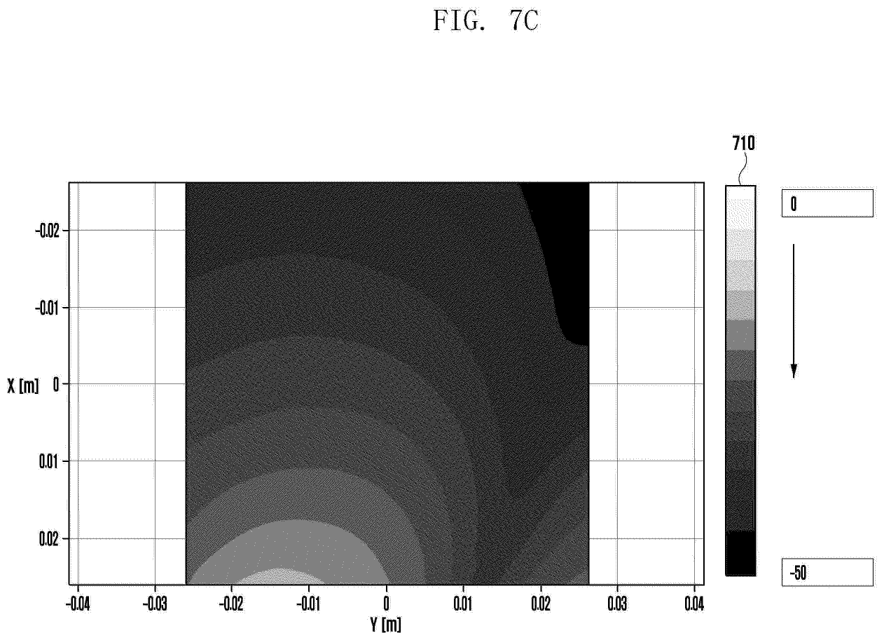

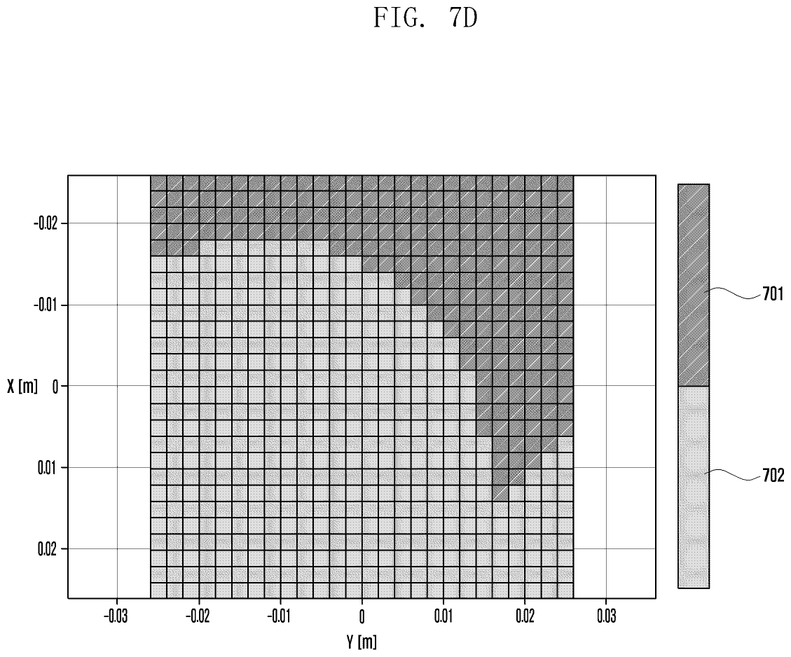

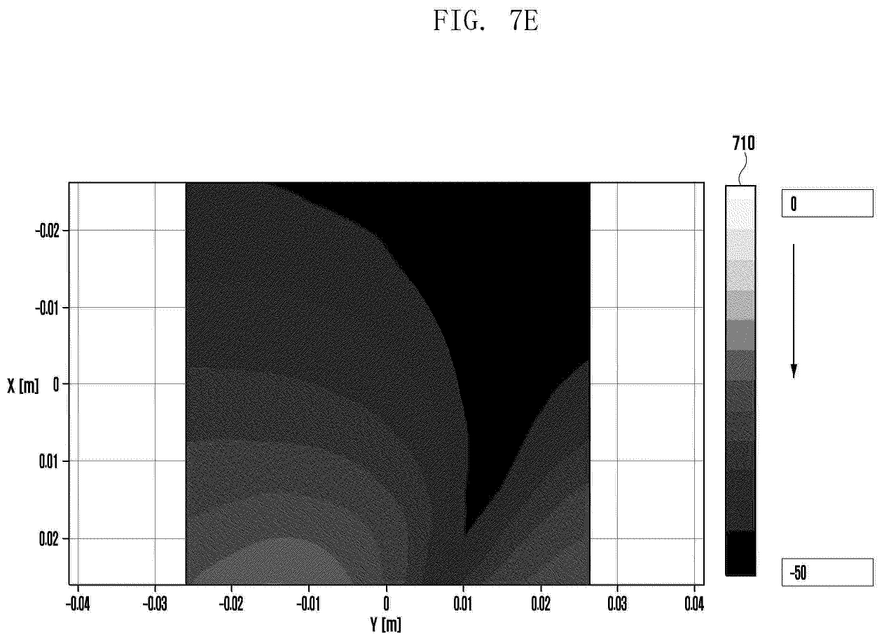

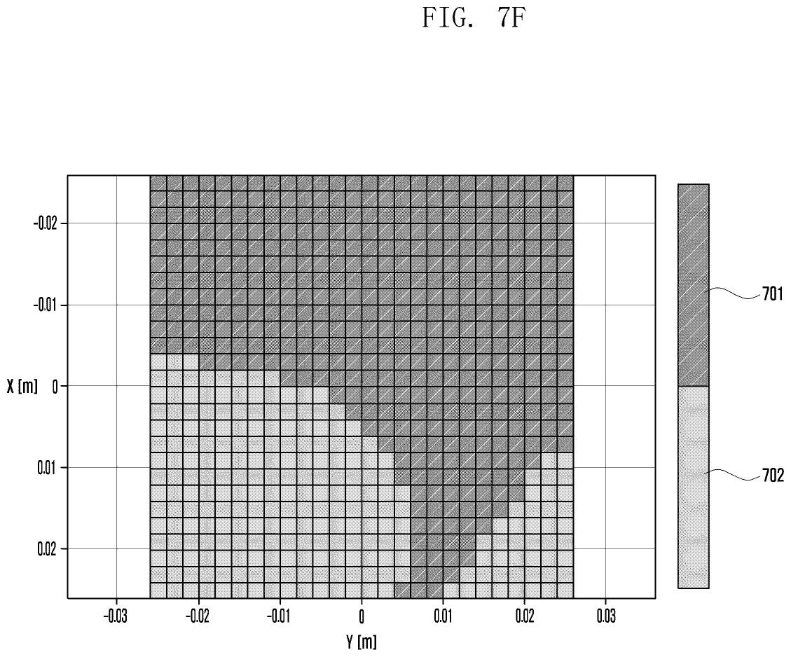

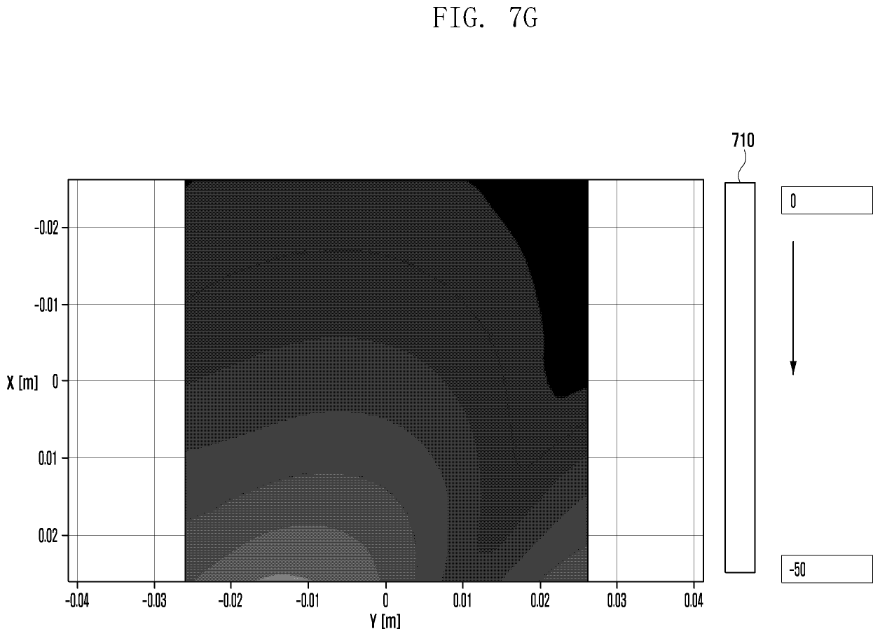

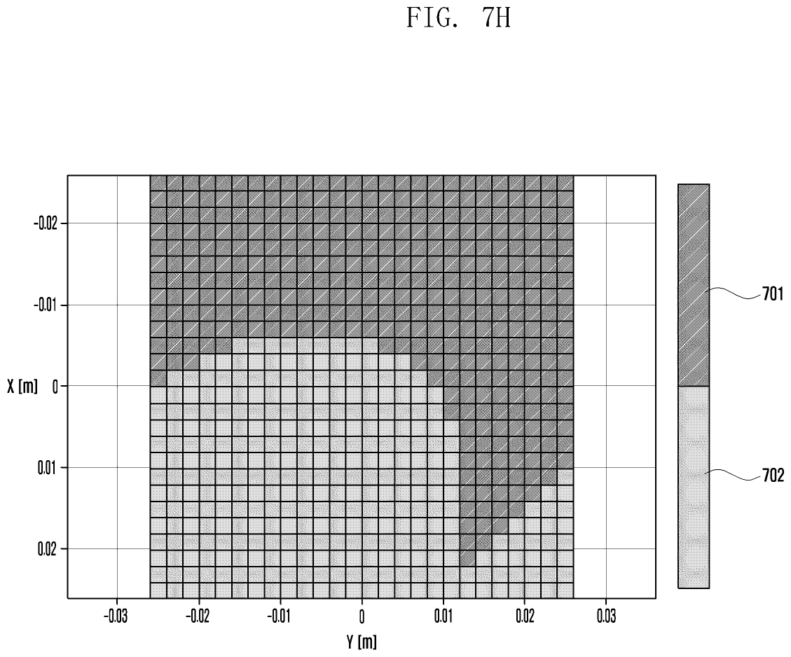

FIG. 7A is a diagram illustrating values of the H-field measured in area A of FIG. 2A for the electronic device 100 when the front surface shield sheet 410 and the rear surface shield sheet 350 are not present according to various embodiments.

FIG. 7B is a diagram classifying the H-field measured in FIG. 7A according to a magnetic field strength standard of the HAC regulations of the FCC according to various embodiments.

Referring to FIGS. 2A, 7A, and 7B, in the graphs of FIGS. 7A and 7B, the x-axis represents the vertical direction of area A (see, e.g., FIG. 2A), and the y-axis represents the horizontal direction of area A. The units of the x-axis and the y-axis may include meters (m).

Referring to FIGS. 7A and 7B, an index 710 representing magnetic field strength may indicate that the magnetic field becomes weaker as lightness decreases. In an embodiment, when an x-value in area A is 0 to 0.02 (m), it may represent a portion of the electronic device 100 in the first edge area 201 of the electronic device 100, and when the x-value is 0 to −0.02 (m), it may represent an external area of the electronic device 100 outside the first edge area 201.

In an embodiment, the magnetic field strength standard according to the HAC regulations of the FCC is −38 dBA/m or less. If the magnetic field strength is identified at each specific point in area A and 300 or more points have a magnetic field strength of −38 dBA/m or less, the HAC regulations of the FCC may be satisfied. For example, each aggregated square included in FIG. 7B may be regarded as one point. However, the disclosure is not limited to defining the HAC regulations of the FCC as 300 points, and a total number of points may be changed according to the HAC regulations of the FCC.

In an embodiment, when the magnetic field strength of the speaker 310 of the electronic device 100 in a mute state is identified at each specific point in area A, and, in the case of Non-2G GSM, 300 or more points have a magnetic field strength of −38 dBA/m or less, the HAC regulations of the FCC may be satisfied.

In an embodiment, when the magnetic field strength of the speaker 310 of the electronic device 100 in a mute state is identified at each specific point in area A, and, in the case of 2G GSM, 125 or more points have a magnetic field strength of −38 dBA/m or less, the HAC regulations of the FCC may be satisfied.

In an embodiment, when idle noise is measured in area A in a state in which there is no voice signal during a call operation of the electronic device 100, and points with −38 dBA/m or less are greater than or equal to the total number of pass points, the HAC regulations of the FCC may be satisfied.

FIG. 7B illustrates pass points 701 having a magnetic field strength of −38 dBA/m or less and fail points 702 having a magnetic field strength exceeding −38 dBA/m in area A through an HAC regulation test of the FCC, and when the front surface shield sheet 410 and the rear surface shield sheet 350 are not present, the number of pass points 701 is 96, and it may be difficult to satisfy the HAC regulations of the FCC.

FIG. 7C is a diagram illustrating values of the H-field measured in area A of FIG. 2A of the electronic device 100 when only the front surface shield sheet 410 is present according to various embodiments.

FIG. 7D is a diagram classifying the H-field measured in FIG. 7C according to a magnetic field strength standard of the HAC regulations of the FCC according to various embodiments.

Referring to FIGS. 2A, 7C, and 7D, in the graphs of FIGS. 7C and 7D, the x-axis represents the vertical direction of area A (see, e.g., FIG. 2A), and the y-axis represents the horizontal direction of area A. The units of the x-axis and the y-axis may include meters (m).

Referring to FIGS. 7C and 7D, an index 710 representing magnetic field strength may indicate that the magnetic field becomes weaker as lightness decreases. In an embodiment, when an x-value in area A is 0 to 0.02 (m), it may represent a portion of the electronic device 100 in the first edge area 201 of the electronic device 100, and when the x-value is 0 to −0.02 (m), it may represent an external area of the electronic device 100 outside the first edge area 201.

FIG. 7D illustrates pass points 701 having a magnetic field strength of −38 dBA/m or less and fail points 702 having a magnetic field strength exceeding −38 dBA/m in area A through an HAC regulation test of the FCC, and when only the front surface shield sheet 410 is present, the number of pass points 701 may be 274.

In this case, although the number of pass points 701 is improved compared to when the front surface shield sheet 410 and the rear surface shield sheet 350 are not present, it may still be difficult to satisfy the HAC regulations of the FCC.

FIG. 7E is a diagram illustrating values of the H-field measured in area A of FIG. 2A of the electronic device 100 which includes the front surface shield sheet 410 and the rear surface shield sheet 350 including the slit 351 according to various embodiments.

FIG. 7F is a diagram classifying the H-field measured in FIG. 7E according to a magnetic field strength standard of the HAC regulations of the FCC according to various embodiments.

Referring to FIGS. 2A, 7E, and 7F, in the graphs of FIGS. 7E and 7F, the x-axis represents the vertical direction of area A (see, e.g., FIG. 2A), and the y-axis represents the horizontal direction of area A. The units of the x-axis and the y-axis may include meters (m). Referring to FIGS. 7E and 7F, an index 710 representing magnetic field strength may indicate that the magnetic field becomes weaker as lightness decreases.

In an embodiment, when an x-value in area A is 0 to 0.02 (m), it may represent a portion of the electronic device 100 in the first edge area 201 of the electronic device 100, and when the x-value is 0 to −0.02 (m), it may represent an external area of the electronic device 100 outside the first edge area 201.

FIG. 7E illustrates pass points 701 having a magnetic field strength of −38 dBA/m or less and fail points 702 having a magnetic field strength exceeding −38 dBA/m in area A through an HAC regulation test of the FCC, and when the electronic device 100 includes the front surface shield sheet 410 and the rear surface shield sheet 350 including the slit 351, the number of pass points 701 may be 430. In this case, the HAC regulations of the FCC may be satisfied.

FIG. 7G is a diagram illustrating values of the H-field measured in area A of FIG. 2A of the electronic device 100 which includes the front surface shield sheet 410 and the rear surface shield sheet 350 including the opening 352 according to various embodiments.

FIG. 7H is a diagram classifying the H-field measured in FIG. 7G according to a magnetic field strength standard of the HAC regulations of the FCC according to various embodiments.

Referring to FIGS. 2A, 7G, and 7H, in the graphs of FIGS. 7E and 7F, the x-axis represents the vertical direction of area A (see, e.g., FIG. 2A), and the y-axis represents the horizontal direction of area A. The units of the x-axis and the y-axis may include meters (m).

Referring to FIGS. 7G and 7H, an index 710 representing magnetic field strength may indicate that the magnetic field becomes weaker as lightness decreases.

In an embodiment, when an x-value in area A is 0 to 0.02 (m), it may represent a portion of the electronic device 100 in the first edge area 201 of the electronic device 100, and when the x-value is 0 to −0.02 (m), it may represent an external area of the electronic device 100 outside the first edge area 201.

FIG. 7H illustrates pass points 701 having a magnetic field strength of −38 dBA/m or less and fail points 702 having a magnetic field strength exceeding −38 dBA/m in area A through an HAC regulation test of the FCC, and when the electronic device 100 includes the front surface shield sheet 410 and the rear surface shield sheet 350 including the slit 351, the number of pass points 701 may be 353. In this case, the HAC regulations of the FCC may be satisfied.

In an example embodiment, an electronic device 100 may include a speaker 310, a display 140 disposed on a front surface of the electronic device 100, a cover 210 disposed on a rear surface of the electronic device 100, a printed circuit board 320 including radio frequency (RF) circuitry including at least one of a power amplifier or a power management IC spaced apart from the speaker 310, a battery 340 spaced apart from the printed circuit board 320 by a second specified distance, a first shield sheet (e.g., the front surface shield sheet 410) corresponding to at least a portion of the battery 340 and the printed circuit board 320 and disposed between the display 140 and the printed circuit board 320, and a second shield sheet (e.g., a rear surface shield sheet 350) corresponding to at least a portion of the battery 340 and the printed circuit board 320 and disposed between the cover 210 and the battery 340 and the printed circuit board 320. The second shield sheet may include an opening 352 in an area adjacent to the RF circuitry and is configured to radiate a magnetic field generated by the RF circuitry through the opening 352.

In an example embodiment, the electronic device 100 may include at least one coil disposed on the second shield sheet (e.g., a rear surface shield sheet 350).

In an example embodiment, the second shield sheet (e.g., the rear surface shield sheet 350) may be separated into two sheets by a slit 351 or a slit-shaped opening.

In an example embodiment, the display 140 may include a copper sheet on the rear surface thereof.

In an example embodiment, the opening 352 may be positioned between an area corresponding to the RF circuitry and an area corresponding to the battery.

In an example embodiment, the slit 351 may be positioned between an area corresponding to the RF circuitry and an area corresponding to the battery.

In an example embodiment, the slit 351 may have a specified interval.

In an example embodiment, the second shield sheet (e.g., a rear surface shield sheet 350) may include an opening 352 in an area corresponding to at least a portion of the RF circuitry.

In an example embodiment, at least one of the first shield sheet (e.g., a front surface shield sheet 410) and the second shield sheet (e.g., a rear surface shield sheet 350) may be spaced apart from the speaker 310 by a specified distance.

In an example embodiment, the first shield sheet (e.g., the front surface shield sheet 410) and the second shield sheet (e.g., the rear surface shield sheet 350) may include at least one of a high-permeability magnetic material or a conductive metal.

In an example embodiment, the opening 352 may correspond to an area in which a high-permeability magnetic material or a conductive metal is removed.

In an example embodiment, the second shield sheet (e.g., the rear surface shield sheet 350) may have a step between the opening 352 and an area other than the opening 352.

In an example embodiment, the slit 351 may correspond to an area in which a high-permeability magnetic material or a conductive metal is removed.

In an example embodiment, the second shield sheet (e.g., a rear surface shield sheet 350) may have a step between the slit 351 and an area other than the slit 351.

In an example embodiment, the electronic device 100 may include at least one processor 110 and memory 120 configured to store instructions. The instructions, when executed individually or collectively by the at least one processor 110, may cause the electronic device 100 to request a base station to restrict application of uplink multiple input multiple output (MIMO) based on a hearing aid being communicatively connected and used for a call.

In an example embodiment, a magnetic field shield sheet (e.g., the rear surface shield sheet 350) may include a first cover layer 210, a second cover layer 210, and a shield layer disposed between the first cover layer 210 and the second cover layer 210 and including a high-permeability magnetic material. The shielding layer may include a slit area 351 or an opening area 352 in which the high-permeability magnetic material is removed.

In an example embodiment, the magnetic field shield sheet (e.g., the rear surface shield sheet 350) may have a step between the slit area 351 or the opening area 352 and an area other than the slit area 351 or the opening area 352.

In an example embodiment, the slit 351 area of the magnetic field shield sheet (e.g., the rear surface shield sheet 350) may include a magnetic shield sheet (e.g., the rear surface shield sheet 350) having a specified interval.

In an example embodiment, the slit area 351 or the opening area 352 of the magnetic field shield sheet (e.g., the rear surface shield sheet 350) may allow a magnetic field to be radiated.

In an example embodiment, the slit area 351 of the magnetic field shield sheet (e.g., the rear surface shield sheet 350) may be disposed in a specified direction.

The electronic device according to an embodiment may be one of various types of electronic devices. The electronic device may include, for example, a portable communication device (e.g., a smart phone), a computer device, a portable multimedia device, a portable medical device, a camera, a wearable device, a home appliance, or the like. The electronic device according to embodiments of the disclosure is not limited to those described above.

It should be appreciated that the various example embodiments and the terms used therein are not intended to limit the technological features set forth herein to particular embodiments and the disclosure includes various changes, equivalents, or alternatives for a corresponding embodiment. With regard to the description of the drawings, similar reference numerals may be used to designate similar or relevant elements. A singular form of a noun corresponding to an item may include one or more of the items, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one or all possible combinations of the items enumerated together in a corresponding one of the phrases. Such terms as “a first,” “a second,” “the first,” and “the second” may be used to simply distinguish a corresponding element from another, and does not limit the elements in other aspect (e.g., importance or order). If an element (e.g., a first element) is referred to, with or without the term “operatively” or “communicatively”, as “coupled with/to” or “connected with/to” another element (e.g., a second element), the element may be coupled/connected with/to the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. The “module” may be a single integrated component, or a minimum unit or part thereof, adapted to perform one or more functions. For example, according to an embodiment, the “module” may be implemented in the form of an application-specific integrated circuit (ASIC).

An embodiment as set forth herein may be implemented as software (e.g., a program) including one or more instructions that are stored in a storage medium (e.g., an internal memory or external memory) that is readable by a machine (e.g., the electronic device 100). For example, a processor (e.g., the processor 100) of the machine (e.g., the electronic device 120) may invoke at least one of the one or more instructions stored in the storage medium, and execute it. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Herein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, methods according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to an embodiment, each element (e.g., a module or a program) of the above-described elements may include a single entity or multiple entities, and some of the multiple entities may also be separately disposed in another element. According to an embodiment, one or more of the above-described elements may be omitted, or one or more other elements may be added. Alternatively or additionally, a plurality of elements (e.g., modules or programs) may be integrated into a single element. In such a case, according to various embodiments, the integrated element may still perform one or more functions of each of the plurality of elements in the same or similar manner as they are performed by a corresponding one of the plurality of elements before the integration. According to various embodiments, operations performed by the module, the program, or another element may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various modifications, alternatives and/or variations of the various example embodiments may be made without departing from the true technical spirit and full technical scope of the disclosure, including the appended claims and their equivalents. It will also be understood that any of the embodiment(s) described herein may be used in conjunction with any other embodiment(s) described herein.

What is claimed is:

1. An electronic device comprising:
a speaker;
a display disposed on a front surface of the electronic device;
a cover disposed on a rear surface of the electronic device;
a printed circuit board comprising radio frequency (RF) circuitry comprising at least one of a power amplifier or a power management integrate circuit (IC) spaced apart from the speaker;
a battery spaced apart from the printed circuit board;
a first shield sheet corresponding to at least a portion of the battery and the printed circuit board and disposed between the display and the printed circuit board, the first shield sheet being configured to shield a magnetic field generated by the RF circuitry from being directed toward the front surface; and
a second shield sheet corresponding to at least a portion of the battery and the printed circuit board and disposed between the cover and the battery and the printed circuit board, the second shield sheet comprising an opening in an area adjacent to the RF circuitry and being configured to radiate a magnetic field generated by the RF circuitry through the opening.

2. The electronic device of claim 1, further comprising:
at least one coil disposed on the second shield sheet.

3. The electronic device of claim 1, wherein the second shield sheet is separated into two sheets by a slit and/or a slit-shaped opening.

4. The electronic device of claim 1, wherein the display comprises a copper sheet on a rear surface thereof.

5. The electronic device of claim 1, wherein the opening is positioned between an area corresponding to the RF circuitry and an area corresponding to the battery.

6. The electronic device of claim 3, wherein the slit is formed in a cross direction of the electronic device.

7. The electronic device of claim 3, wherein the slit is positioned between an area corresponding to the RF circuitry and an area corresponding to the battery.

8. The electronic device of claim 1, wherein the second shield sheet comprises an opening in an area corresponding to at least a portion of the RF circuitry.

9. The electronic device of claim 1, wherein at least one of the first shield sheet and the second shield sheet is spaced apart from the speaker by a specified distance.

10. The electronic device of claim 3, wherein the first shield sheet and the second shield sheet comprise at least one of a high-permeability magnetic material having a permeability greater than a threshold permeability and/or a conductive metal.

11. The electronic device of claim 10, wherein the opening corresponds to an area in which a high-permeability magnetic material and/or a conductive metal is not present.

12. The electronic device of claim 11, wherein the second shield sheet includes a step between the opening and an area other than the opening.

13. The electronic device of claim 10, wherein the slit corresponds to an area in which the high-permeability magnetic material and/or a conductive metal is not present.

14. The electronic device of claim 13, wherein the second shield sheet includes a step between the slit and an area other than the slit.

15. The electronic device of claim 1, further comprising:
at least one processor comprising processing circuitry; and
memory configured to store instructions,
wherein at least one processor, individually and/or collectively, is configured to execute the instructions and to cause the electronic device to request a base station to restrict application of uplink multiple input multiple output (MIMO) based on a hearing aid being communicatively connected and used for a call.

16. A magnetic field shield sheet comprising:
a first cover layer;
a second cover layer; and
a shield layer disposed between the first cover layer and the second cover layer and comprising a high-permeability magnetic material having a permeability greater than a threshold permeability,
wherein the shield layer comprises a slit area and/or an opening area in which the high-permeability magnetic material is not present.

17. The magnetic field shield sheet of claim 16, wherein a step is included between the slit area or the opening area and an area other than the slit area and/or the opening area.

18. The magnetic field shield sheet of claim 16, wherein the slit area has a specified interval.

19. The magnetic field shield sheet of claim 16, wherein the slit area and/or the opening area is configured to allow a magnetic field to be radiated.

20. The magnetic field shield sheet of claim 16, wherein the slit area is disposed in a specified direction.
